(19) United States
(12) Patent Application Publication
(10) Pub. No.: US 2014/0322925 A1
(43) Pub. Date: Oct. 30, 2014

(54) METHOD OF LASER ANNEALING PROCESS

(71) Applicant: EverDisplay Optronics (Shanghai) Limited, Shanghai (CN)

(72) Inventors: ChangHan Chiang, Shanghai (CN); YuChun Yeh, Shanghai (CN)

(73) Assignee: EverDisplay Optronics (Shanghai) Limited, Shanghai (CN)

(21) Appl. No.: 14/092,713

(22) Filed: Nov. 27, 2013

(30) Foreign Application Priority Data
Apr. 26, 2013 (CN) 201310151573.X

(51) Int. Cl. H01L 21/02

(52) U.S. Cl. CPC H01L 21/02686
USPC 438/795

(57) ABSTRACT

The present disclosure discloses a method of laser annealing process, wherein the surface of the semiconductor structure on a substrate is scanned by a laser annealing device, and the said laser annealing device comprises a laser source and the optical instruments. The invention comprises the following steps: generating a laser beam by the laser source, and the laser beam is irradiating on a mirror, the route thereof changed by 90 degrees and converging the laser beam by the optical instrument thereafter. By this method, an improved annealing process which saved the chamber, reduced the likelihood of the oxidation of silicon film in the annealing process, improved the electrical property of silicon substrate, reduced the weight of machine and further simplified the maintenance machine.

### CROSS-REFERENCE TO RELATED APPLICATIONS

The present application claims priority to and the benefit of Chinese Patent Application No. CN 201310151573.X, filed on Apr. 26, 2013, the entire content of which is incorporated herein by reference.

### BACKGROUND OF THE INVENTION

1. Field of the Invention

The present disclosure relates to the technology of laser annealing, more specifically, to a method of utilizing laser to anneal the amorphous silicon for improving the electrical property of the polysilicon which is transformed from the amorphous silicon.

2. Description of the Related Art

The art of high temperature furnace annealing or the process of excimer laser system annealing is usually adopted in the process of transforming the amorphous silicon to polysilicon. However, the over long time of heating thereof causes the oxidation of silicon film. And it is necessary to fill the nitrogen in a huge chamber. U.S. Pat. No. 6,027,960 adopted an excimer laser with the wavelength of 308 nm to irradiate the surface of amorphous silicon. As shown in FIG. 1, the amorphous silicon on the surface of the substrate is transformed into a polysilicon by the tempering process. The substrate is placed on a machine with Chamber 101 which is filled with the nitrogen by the gas pipeline in order to reducing the contacting of the amorphous silicon on the substrate surface and oxygen in the tempering process. Due to big size of the Chamber 101 and additionally necessary gas pipeline, the machine requires a relatively big space. It is heavy and is with higher maintenance cost.

U.S. Patent No. 20110157080A has disclosed a user interface system that includes a sheet that defines a surface and at least partially defines a fluid vessel arranged underneath the surface, a volume of fluid within the fluid vessel, a displacement device that influences the volume of the fluid within the fluid vessel to expand and contract at least a portion of the fluid vessel, thereby deforming a particular region of the surface, and a sensor system that is configured to receive a user input on the surface with a first sensitivity and configured to receive a user input substantially proximal to the particular region of the surface at with second sensitivity higher than the first sensitivity. However, it did not solve the problem of over long time of heating and the consequence thereof such as serious oxidation of silicon film.

### SUMMARY OF THE INVENTION

An embodiment of the present disclosure is directed toward a method of laser annealing process capable of reducing the likelihood of the oxidation of silicon film in the annealing process, improving the electrical property of silicon substrate, reducing the weight of machine, and simplifying the maintenance machine.

The method of laser annealing process comprising: generating a Laser Beam (0) by a Laser Source (2); reflecting and converging the laser beam; scanning Amorphous Silicon (11) on the surface of a Substrate (1) at a predetermined speed by Laser Beam (0); wherein, the Laser Beam (0) is generated in pulse train; the pulse train includes M groups of pulse train, where the each train includes N pulse; M and N are the natural numbers bigger than 1.

The pulse interval between each laser pulse train is 20 ms. The duration of laser pulse train is less than 50 ns. The pulse width of the pulse is less than 10 ps. The wavelength of the Laser Beam (0) is 523 nm or 527 nm or 532 nm. The said optical instrument consists of a convex lens or a plurality of convex lenses. The laser source is the XeCl laser device. The laser source is the KrF laser device. The heating temperature of the laser annealing process which heats the bottom of the said substrate ranges from 100° C. to 700° C.

### BRIEF DESCRIPTIONS OF THE DRAWINGS

The accompanying drawings, together with the specification, illustrate exemplary embodiments of the present disclosure, and, together with the description, serve to explain the principles of the present invention.

FIG. 1 shows structure diagram of the laser annealing device in the prior art;

FIG. 2 shows flow diagram of the method of the present disclosure;

FIG. 3 shows a structure diagram of the laser annealing device of the present disclosure;

FIG. 4 shows a diagram of the laser pulse train of the present disclosure.

### DETAILED DESCRIPTION

Hereinafter, certain exemplary embodiments according to the present disclosure will be described with reference to the accompanying drawings.

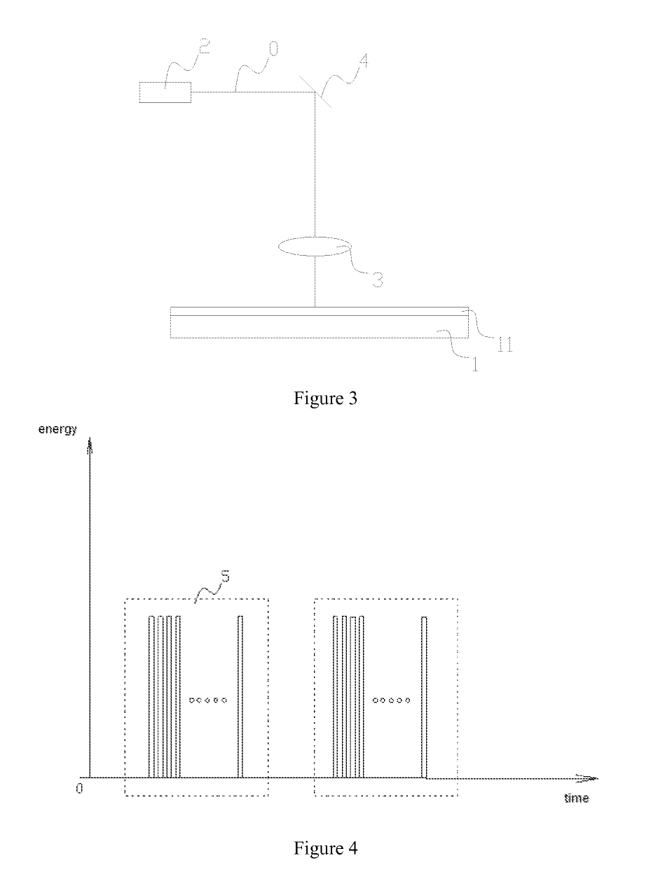

FIG. 3 shows a structure diagram of the laser annealing device of the present disclosure. The surface of the semiconductor on Substrate 1 is scanned by a laser annealing device. The laser annealing device comprises a Laser Source 2 and an Optical Instrument 3. The laser annealing device can be placed on the machine. Further, this machine is not provided with a chamber inside.

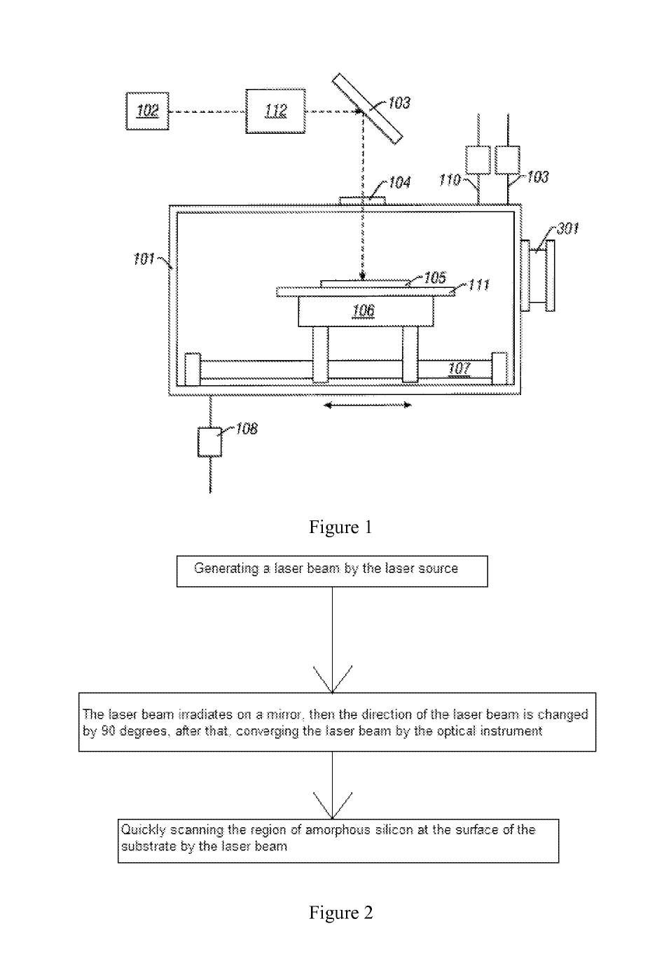

FIG. 2 shows the method of laser annealing process comprising the following steps:

Generating a Laser Beam 0 by Laser Source 2 with the preferred an ultrashort wave laser wavelength of Laser Beam 0 of 532 nm, which can alternatively be 527 nm or 523 nm and so on.

Then Laser Beam 0 irradiates on a Mirror 4 which is a flat surface reflector. Mirror 4 is disposed in the route of Laser Beam 0, which is 45 degree of the horizontal.

Therefore, the route of Laser Beam 0 changes 90 degree after reflection on Mirror 4. And Laser Beam 0 converges through Optical Instrument 3. Optical Instrument 3 is preferred to consist of single convex lens or a plurality of convex lenses which is easy to achieve in the market.

Scanning Amorphous Silicon Region 11, the surface of Substrate 1, by Laser Beam 0, in particular, Laser Beam 0 is generated in the form of laser pulse train. FIG. 4 shows the time frequency of the laser pulse train, wherein the horizontal axis denotes time, and the longitudinal axis denotes the energy of the laser source pulsed radiation.

In this embodiment, the pulse train includes M groups of Pulse Train 5, which is shown in the inner dashed box. Each Pulse Train 5 includes N pulses. M and N are natural number bigger than 1. The value of N is determined by the length of the Pulse Train 5 and the width of the pulse.

Preferably, the pulse interval between etch Pulse Train 5 is 20 ms, the duration of Pulse Train 5 is less than 50 ns, and the width of each pulse is less than 10 ps. The pulses is generated in densely speed, and the width of each pulse is extremely short. Hence, the time of the pulses reaching the surface of the crystal is shortened in a small and limited range. Consequently, it greatly reduces the time for the surface of the amorphous silicon being exposed in the air during the annealing process. The time of the molecular at the surface of the amorphous silicon contacting with the oxygen is reduced. To a great extent, the said process isolates the said molecular from the oxygen even that the process is not performed in the airtight chamber with the inert gas. The likelihood of oxidation of the silicon film is reduced to the lowest.

The pulse width and the pulse interval of the Pulse Train 5 can be set by adjusting the corresponding parameters of laser source without the impact on the structure of the laser source.

Preferably, Laser Source 2 is the ultrafast laser device controlled by the acousto-optic Q-switching, the electro-optical Q-switching, the mode-locking technology and pulse train of MOPA. The preferred energy of ultrafast laser device ranges from 100 mJ/cm² to 500 mJ/cm², which can be adjusted to the specific requirements. The laser device varies from other type(s) than above.

The bottom of the substrate is heated in the process of laser annealing, and the temperature ranges from 100° C. to 700° C. which ensures that the amorphous silicon molecules can maximally transform into the polycrystalline silicon molecules with the scanning by the pulse train of Laser Source 2.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof

What claimed is:

1. A method of laser annealing process, comprising:
(a) generating a Laser Beam (0) by a Laser Source (2);
(b) reflecting and converging the laser beam;
(c) scanning Amorphous Silicon (11) on the surface of a Substrate (1) at a predetermined speed by Laser Beam (0);
wherein, the Laser Beam (0) is generated in pulse train; the pulse train includes M groups of pulse train, where the each train includes N pulse; M and N are the natural numbers bigger than 1.

2. A method of laser annealing process as disclosed in claim 1, wherein the pulse interval between each laser pulse train is 20 ms.

3. A method of laser annealing process as disclosed in claim 2, wherein the duration of laser pulse train is less than 50 ns.

4. A method of laser annealing process as disclosed in claim 2, wherein the pulse width of the pulse is less than 10 ps.

5. A method of laser annealing process as disclosed in claim 3, wherein the wavelength of the laser beam (0) is 523 nm or 527 nm or 532 nm.

6. A method of laser annealing process as disclosed in claim 4, wherein the wavelength of the laser beam (0) is 523 nm or 527 nm or 532 nm.

7. A method of laser annealing process as disclosed in claim 5, wherein the said optical instrument consists of a convex lens or a plurality of convex lenses.

8. A method of laser annealing process as disclosed in claim 6, wherein the said optical instrument consists of a convex lens or a plurality of convex lenses.

9. A method of laser annealing process as disclosed in claim 7, wherein the laser source is the XeCl laser device.

10. A method of laser annealing process as disclosed in claim 8, wherein the laser source is the XeCl laser device.

11. A method of laser annealing process as disclosed in claim 7, wherein the laser source is the KrF laser device.

12. A method of laser annealing process as disclosed in claim 8, wherein the laser source is the KrF laser device.

13. A method of laser annealing process as disclosed in claim 1, wherein the heating temperature of the laser annealing process which heats the bottom of the said substrate ranges from 100° C. to 700° C.
